(19) United States
(12) Patent Application Publication
(10) Pub. No.: US 2025/0069963 A1
(43) Pub. Date: Feb. 27, 2025

(54) SEMICONDUCTOR DEVICE

(71) Applicant: FUJI ELECTRIC CO., LTD., Kawasaki-shi, Kanagawa (JP)

(72) Inventor: Reika UCHIMI, Kawasaki-shi (JP)

(73) Assignee: FUJI ELECTRIC CO., LTD., Kawasaki-shi, Kanagawa (JP)

(21) Appl. No.: 18/756,164

(22) Filed: Jun. 27, 2024

(30) Foreign Application Priority Data
Aug. 24, 2023 (JP) 2023-136174

(51) Int. Cl. H01L 23/057; H01L 23/498

(52) U.S. Cl. CPC H01L 23/057; H01L 23/49811

(57) ABSTRACT

A semiconductor device, including: a semiconductor element; a main terminal that includes a fastening portion including a fastening hole, through which the main terminal is fastenable to an external conductor by a screw and a nut, and an extending portion extending from a first side of the fastening portion toward the semiconductor element, the extending portion being electrically connected to the semiconductor element; and a case that houses the semiconductor element. The case has a recess configured to accommodate the nut fastening the main terminal through the fastening hole. The main terminal further includes a bent portion that is bent from a peripheral edge of the fastening portion at a second side thereof different from the first side, and that is disposed between a wall surface of the recess in the case and the nut fastening the main terminal through the fastening hole.

### CROSS-REFERENCE TO RELATED APPLICATION

The present application claims priority pursuant to 35 U.S.C. § 119 from Japanese patent application number 2023-136174 filed on Aug. 24, 2023, the entire disclosure of which is hereby incorporated by reference herein.

### BACKGROUND OF THE INVENTION

### 1. Technical Field

The present invention relates to a semiconductor device including a case that houses a nut for fastening an external conductor to a main terminal.

### 2. Description of the Related Art

Conventionally, there is a semiconductor device including a main terminal electrically connected to a semiconductor element such as an insulated gate bipolar transistor (IGBT) and to an external conductor (see, for example, JP H06-120390 A, JP 2002-076255 A, JP 2022-096958 A, and JP 2021-190553 A). In addition, fastening by bolts is employed as a method of fixing a plurality of members (see, for example, JP 2002-039141 A and JP 2012-209165 A).

There is a semiconductor device in which a case accommodating a semiconductor element accommodates a nut for fastening an external conductor to a main terminal. In this type of semiconductor device, torque is applied to the case from the nut when the external conductor is fastened to the main terminal by the screw. Accordingly, for example, a configuration for ensuring the strength of the case, such as a configuration in which the case is thick, is adopted, whereby it is difficult to downsize the semiconductor device.

An object of the present invention is to provide a semiconductor device capable of alleviating torque applied to the case when an external conductor is fastened to a main terminal.

### SUMMARY OF THE INVENTION

According to one aspect, a semiconductor device includes: a semiconductor element; a main terminal that includes a portion to be fastened including a fastening hole and fastened to an external conductor by a screw and a nut through the fastening hole, and an extending portion extending from the portion to be fastened toward the semiconductor element and electrically connected to the semiconductor element; and a case that houses the semiconductor element, in which the case has a recess that accommodates the nut, and the main terminal further incudes a bent portion that is bent from a peripheral edge of the portion to be fastened different from a side of the extending portion, and enters between a wall surface of the recess in the case and the nut.

According to the above aspect, torque applied to the case when the external conductor is fastened to the main terminal can be alleviated.

### BRIEF DESCRIPTION OF THE DRAWINGS

FIG. 1 is a plan view illustrating a semiconductor device according to an embodiment;

FIG. 2 is a right side view illustrating an internal configuration of the semiconductor device according to the embodiment in a perspective manner;

FIGS. 3A to 3D are a plan view, a front view, a right side view, and a developed view of a P terminal according to the embodiment;

FIGS. 4A to 4D are a plan view, a front view, a right side view, and a developed view of a P terminal according to a first modification of the embodiment;

FIGS. 5A to 5D are a plan view, a front view, a right side view, and a developed view of a P terminal according to a second modification of the embodiment;

FIGS. 6A to 6D are a plan view, a front view, a right side view, and a developed view of a P terminal according to a third modification of the embodiment;

FIG. 7 is a developed view of a P terminal according to a fourth modification of the embodiment; and

FIG. 8 is a developed view of a P terminal according to a fifth modification of the embodiment.

### DETAILED DESCRIPTION

A semiconductor device according to an embodiment of the present invention will be described below with reference to the drawings. Note that the present invention is not limited to the following embodiment and thus appropriate modifications can be made without departing from the gist of the present invention.

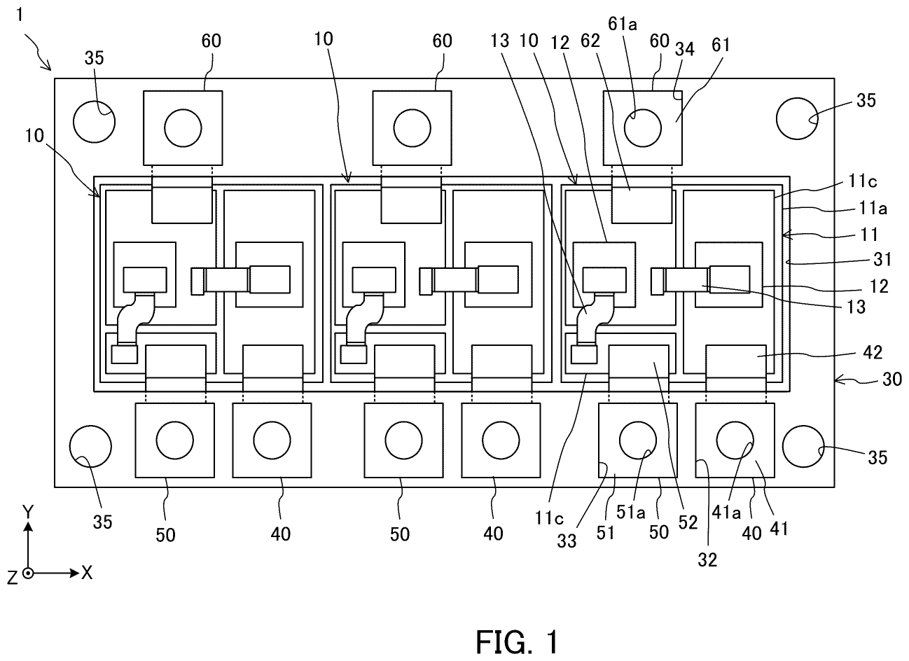

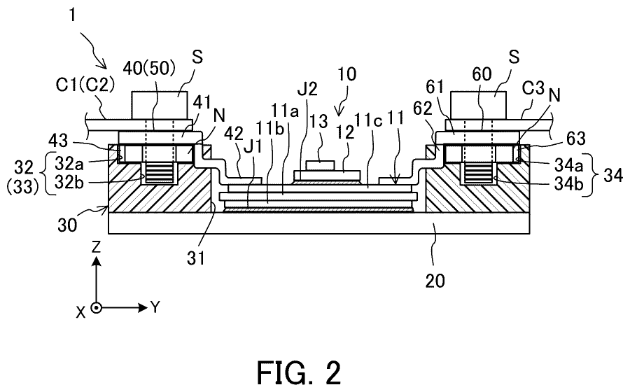

FIGS. 1 and 2 are a plan view of a semiconductor device 1 according to an embodiment and a right side view illustrating an internal configuration in a perspective manner.

Note that, from among X, Y, and Z directions indicated in FIGS. 1 and 2 and FIGS. 3A to 6D to be described later, the Z direction is defined as the up-down direction of the semiconductor device 1 (thickness direction of a laminate substrate 11). The X and Y directions orthogonal to the Z direction are defined, respectively, as the longitudinal direction of the semiconductor device 1 and the lateral direction of the semiconductor device 1, respectively. In some cases, the X direction may be referred to as a right-left direction, the Y direction may be referred to as a front-rear direction, and the Z direction may be referred to as an up-down direction. Such directional terms are used for convenience of description. Thus, depending on the posture of attachment of the semiconductor device 1, the correspondence relationship with the X, Y, and Z directions varies.

The semiconductor device 1 according to the present embodiment is applied, for example, to a power converter, such as a power control unit, and serves as a power semiconductor module for an inverter circuit. The application of the semiconductor device 1 is arbitrary, but the semiconductor device 1 is used as, for example, an inverter device for in-vehicle use or an industrial motor.

The semiconductor device 1 illustrated in FIG. 1 includes, for example, three unit modules 10, a metal base 20 (see FIG. 2), a case 30, and a P terminal 40, an N terminal 50, and an M terminal 60 arranged for each unit module 10. For example, the semiconductor device 1 is used together with a cooler (not illustrated) disposed below the metal base 20 in a state where a sealing resin or gel (not illustrated) is injected into the case 30.

The unit module 10 includes a laminate substrate 11, a semiconductor element 12 disposed on the laminate substrate 11, and a metal wiring board 13. In the present embodiment, the three unit modules 10 are disposed side by side in the X direction. The three unit modules 10 achieve, for example, U, V, and W phases, resulting in formation of a three-phase inverter circuit. Note that the unit modules 10 may be each referred to as a power cell or semiconductor unit. The number of unit modules 10 to be disposed is at least one.

The laminate substrate 11 includes, for example, a direct copper bonding (DCB) substrate, an active metal brazing (AMB) substrate, or a metal base substrate. As illustrated in FIG. 2, the laminate substrate 11 includes an insulator 11a, a heat dissipator 11b disposed on the lower face of the insulator 11a, and a plurality of circuit boards 11c disposed on the upper face of the insulator 11a. For example, the laminate substrate 11 is rectangular in shape in plan view.

For example, the insulator 11a is formed of an insulating material, such as a ceramic material (e.g., aluminum oxide (Al₂O₃), aluminum nitride (AlN), silicon nitride (Si₃N₄), or a composite material of aluminum oxide and zirconium oxide (ZrO₂)), a resin material (e.g., epoxy), or an epoxy resin material with a ceramic material as a filler. The insulator 11a may be referred to as an insulating layer or an insulating film.

The heat dissipator 11b has a predetermined thickness in the Z direction and is formed on the lower face of the insulator 11a. For example, the heat dissipator 11b is made of a metal plate having good thermal conductivity, such as copper and aluminum. The heat dissipator 11b is bonded to an upper face of the metal base 20 by a bonding material J1 such as solder.

As illustrated in FIG. 1, three circuit boards 11c are formed on the upper face of the insulator 11a. The number of circuit boards 11c formed on the upper face of the insulator 11a may be any number of one or more. The circuit boards 11c are metal layers such as copper foils, and are formed in island shapes in a mutually electrically isolated state on the insulator 11a. Note that the circuit boards 11c may be each referred to as a circuit layer.

As illustrated in FIG. 2, the semiconductor element 12 is disposed on a mounting face, which is an upper face of the laminate substrate 11 (circuit board 11c), via a bonding material J2. In FIG. 1, two semiconductor elements 12 are illustrated per single laminate substrate 11, but the number of semiconductor elements 12 is arbitrary. For example, the semiconductor elements 12 are each achieved with a semiconductor substrate based on silicon (Si), silicon carbide (SIC), gallium nitride (GaN), or diamond, and are each square or rectangular in shape in plan view.

Note that the semiconductor element 12 include a switching element such as an insulated gate bipolar transistor (IGBT) or a power metal oxide semiconductor field effect transistor (MOSFET), and a diode such as a free wheeling diode (FWD). Such a switching element and a diode may be made in antiparallel connection. As the semiconductor element 12, used may be a reverse conducting (RC)-IGBT element of an IGBT and an FWD in unification, a power MOSFET element, or a reverse blocking (RB)-IGBT element highly resistant to a reverse bias. In particular, in the RC-IGBT element, the internal circuit can be downsized by bidirectional energization, and in turn, the semiconductor device 1 (laminate substrate 11) can be downsized.

The semiconductor elements 12 are each made in electrically conductive connection with a predetermined circuit board 11c through a metal wiring board 13. For example, the metal wiring board 13 is made of a metal material, such as copper material, copper-alloy-based material, aluminum-alloy-based material, or iron-alloy-based material, and is formed due to folding by pressing or the like. For example, the semiconductor element 12 and the metal wiring board 13 are joined together through a bonding material, such as solder. The metal wiring board 13 may be referred to as a lead frame. Note that, instead of the metal wiring board 13, a connecting member, such as a conductive wire, may be disposed.

The metal base 20 illustrated in FIG. 2 is a rectangular plate-like member. The metal base 20 is a member that functions as a heat conducting member that conducts heat generated by the semiconductor element 12 to the cooler (not illustrated) disposed below the metal base 20, and is formed of a metal plate such as a copper plate or an aluminum plate, for example. The metal base 20 and the cooler are bonded via a thermal conductive material such as a thermal grease or a thermal compound.

As illustrated in FIG. 1, the case 30 is formed in a rectangular frame shape having a hollow portion 31 at the center. The three unit modules 10 described above are housed in the hollow portion 31 rectangular in shape. That is, the three unit modules 10 are housed in the space defined by the frame-shaped case 30.

As illustrated in FIG. 2, the recesses 32, 33, and 34 have nut accommodating portions 32a and 34a and screw accommodating portions 32b and 34b. The recesses 32, 33, and 34 are recessed from the upper surface of the case 30 toward the metal base 20. Although the nut accommodating portion and the screw accommodating portion of the recess 33 are not illustrated, the recess 33 can have the same configuration as the recesses 32 and 34.

The nut accommodating portions 32a and 34a accommodate a nut N screwed onto a threaded portion of a screw S. The shapes of the nut accommodating portions 32a and 34a are arbitrary, but are, for example, rectangular in plan view. The screw S and the nut N are members for fastening the external conductors C1, C2, and C3 to the portions to be fastened 41, 51, and 61 through fastening holes 41a, 51a, and 61a to be described later. As the nut N, any nut such as a hexagonal nut having a hexagonal tubular shape or a hexagonal cap nut in which a female threaded hole is not through can be employed.

The screw accommodating portions 32b and 34b accommodate the tip of the threaded portion of the screw S. The shapes of the screw accommodating portions 32b and 34b are arbitrary, but are, for example, circular in plan view. The screw accommodating portions 32b and 34b are smaller in size in plan view than the nut accommodating portions 32a and 34a, and the nut N is placed on the step portions between the nut accommodating portions 32a and 34a and the screw accommodating portions 32b and 34b. However, it is possible that the nut accommodating portions 32a and 34a and the screw accommodating portions 32b and 34b are same in size in plan view, and the nut accommodating portions 32a and 34a and the screw accommodating portions 32b and 34b are not segmented.

In the example of FIG. 2, the recesses 32, 33, and 34 (nut accommodating portions 32a, 34a) are formed between the side surface of the case 30 on the semiconductor element 12 side and the side surface of the case 30 facing the side surface of the semiconductor element 12 side. In this case, the extending portion 42 passes through the inside of case 30 from the portion to be fastened (i.e., fastening portion) 41, and protrudes toward hollow portion 31 from the side surface of case 30 on the semiconductor element 12 side. Further, the recesses 32, 33, and 34 may be recessed deeper from the upper surface of the case 30 so that at least a part of the portions to be fastened (i.e., fastening portions) 41, 51, and 61 of the terminals 40, 50, and 60 is inserted.

The case 30 has a plurality of through holes 35 along its outer peripheral edge. For example, the through holes 35 each serve as a hole for insertion of a bolt for fixing the semiconductor device 1 and an external device such as a cooler (not illustrated) together.

Note that, for example, as resin for the case 30, any insulating resin can be selected from polyphenylene sulfide (PPS), polybutylene terephthalate (PBT), polybutyl acrylate (PBA), polyamide (PA), acrylonitrile butadiene styrene (ABS), a liquid crystal polymer (LCP), polyether ether ketone (PEEK), polybutylene succinate (PBS), urethane, and silicone. In addition, the resin to be selected may be a mixture of two or more types of resin. The resin may contain a filler (for example, a glass filler) for improvement in strength or functionality.

The sealing resin or gel (not illustrated) injected in the inner space defined by the frame-shaped case 30 seals the space in which the laminate substrate 11 and the semiconductor elements 12 mounted on the laminate substrate 11 are located. The sealing resin is composed of, for example, a thermosetting resin. Preferably, the sealing resin contains one of epoxy, silicone, urethane, polyimide, polyamide, and a polyamide-imide. As the sealing resin, for example, an epoxy resin containing a filler is preferable because of its insulation, heat resistance, and heat dissipation. The gel is, for example, a silicone gel.

The case 30 is provided with main terminals (a P terminal 40, an N terminal 50, and an M terminal 60) that function as external connection terminals for connection with external conductors C1, C2, C3 (see FIG. 2), and a control terminal for control (not illustrated). One P terminal 40, one N terminal 50, and one M terminal 60 are arranged for each unit module 10. The P terminal 40 may be each referred to as a positive terminal (input terminal) or a first main terminal. The N terminal 50 may be each referred to as a negative terminal (output terminal) or a second main terminal. The M terminal 60 may be each referred to as an intermediate terminal (output terminal) or a third main terminal.

The P terminal 40 and the N terminal 50 are located on the negative side in the Y direction with respect to the laminate substrate 11. The M terminal 60 is located on the positive side in the Y direction with respect to the laminate substrate 11. For example, the P terminal 40, the N terminal 50, and the M terminal 60 are made of a metal material, such as copper material, copper-alloy-based material, aluminum-alloy-based material, or iron-alloy-based material, and are preferably formed due to folding by pressing or the like.

The P terminal 40, the N terminal 50, and the M terminal 60 include portions to be fastened 41, 51, and 61 and extending portions 42, 52, and 62 extending from the portions to be fastened 41, 51, and 61 toward the semiconductor element 12.

The portions to be fastened 41, 51, and 61 include fastening holes 41a, 51a, and 61a, and are fastened to the external conductors C1, C2, and C3 by the screw S and the nut N. The portions to be fastened 41, 51, and 61 each have a rectangular shape in plan view. The fastening holes 41a, 51a, and 61a penetrate the portions to be fastened 41, 51, and 61 in the Z direction. For example, the inner peripheral surfaces of the fastening holes 41a, 51a, and 61a each have a constant shape in the height direction. Since the portions to be fastened 41, 51, and 61 are fastened to the external conductors C1, C2, and C3 in a state of being placed on the case 30, it can be said that the portions to be fastened 41, 51, and 61 (the terminals 40, 50, and 60) are held by the case 30. When at least a part of the portions to be fastened 41, 51, and 61 is inserted into the recesses 32, 33, and 34 of the case 30 as described above, the case 30 holds the terminals 40, 50, and 60 in a more stable state.

The extending portions 42, 52, and 62 are bent downward (to the negative side in the Z direction) from the portions to be fastened 41, 51, and 61 extending horizontally, are bent horizontally (to the Y direction), are bent downward (to the negative side in the Z direction) again, and are bent horizontally (to the Y direction) again. The extending portions 42, 52, and 62 are joined to the circuit board 11c or a copper block (not illustrated) provided on the circuit board 11c, at the distal end opposite to the portions to be fastened 41, 51, and 61. The extending portions 42, 52, and 62 are electrically connected to the semiconductor element 12 via the circuit board 11c. The extending portions 42, 52, and 62 may abut on the nut N, for example, at portions bent downward from the portions to be fastened 41, 51, and 61. As described above, the extending portions 42, 52, and 62 extend while being bent from the portions to be fastened 41, 51, and 61, but may extend on the same plane as the portions to be fastened 41, 51, and 61 without being bent from the portions to be fastened 41, 51, and 61. Although the extending portions 42, 52, and 62 are smaller in width in the X direction than the portions to be fastened 41, 51, and 61, the width in the X direction may be equal to or greater than that of the portions to be fastened 41, 51, and 61.

In the above description, since three terminals (the P terminal 40, the N terminal 50, and the M terminal 60) are exemplified as the main terminals, the number of the recesses 32, 33, and 34, the nut N, and the like of the case 30 is also three. However, the number of the main terminals, the recesses 32, 33, and 34, the nut N, and the like in the present embodiment can be any number of one or more.

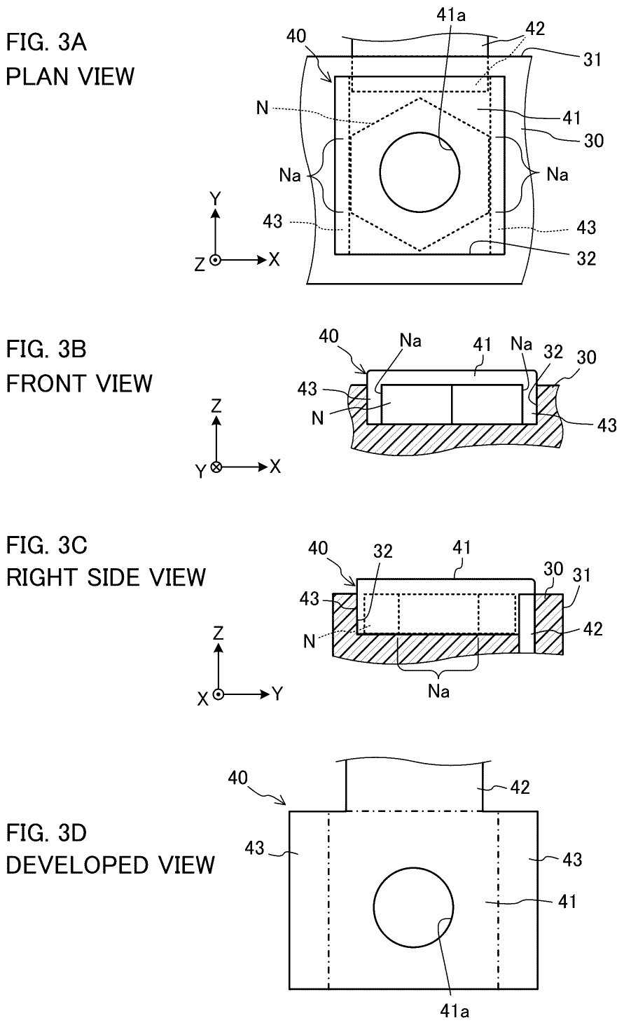

Next, with reference to FIGS. 3A to 3D, details of the bent portions 43 and 63 of the P terminal 40, the N terminal 50, and the M terminal 60 will be described using the P terminal 40 as an example. Note that the bent portion of the N terminal 50 is not illustrated, and the bent portion 63 of the M terminal 60 is only partially shown on the negative side in the X direction of the nut N in FIG. 2, but the N terminal 50 and the M terminal 60 can have the same configuration as the P terminal 40.

FIG. 3A is a plan view, FIG. 3B is a front view, FIG. 3C is a right side view, and FIG. 3D is a developed view of the P terminal 40. A one-dot chain line shown in the development views in FIGS. 3D, 4D, 5D, 6D, 7, and 8 represents a fold line (mountain fold line) of the P terminal 40. In FIGS. 3A to 3D and FIGS. 4A to 6D to be described later, the lead line of the portion indicated by the hidden line (broken line) is indicated by a broken line.

As illustrated in FIGS. 3A to 3D, the P terminal 40 includes the portion to be fastened 41 and the extending portion 42 described above, and a pair of bent portions 43 and 43 bent from the portion to be fastened 41. The bent portions 43 and 43 are bent downward (negative side in the Z direction) from both ends of the portion to be fastened 41 in the width direction (X direction) of the P terminal 40 intersecting the extending direction (Y direction) of the extending portion 42, as an example of a peripheral edge of the portion to be fastened 41 different from the extending portion 42 side (positive side in the Y direction). As illustrated in FIGS. 3A and 3B, the bent portions 43 and 43 enter between the wall surface (left and right side surfaces) of the recess 32 of the case 30 and the nut N.

As shown in FIGS. 3A to 3C, it is desirable that the portion to be fastened 41 and the bent portions 43 and 43 be formed in a size that fits in the recess 32 of the case 30 in plan view, and the bent portions 43 and 43 abut on both the wall surface (left and right side surfaces) of the recess 32 and the side surface Na (left and right side surfaces) of the nut N.

Here, the corner of the front portion of the nut N and the front surface of the recess 32 are preferably spaced apart from each other so that the torque is not directly applied from the nut N to the wall surface of the recess 32 without passing through the bent portion 43. In addition, the corner of the rear portion of the nut N and the extending portion 42 is preferably spaced apart from each other so that a torque is not applied to the extending portion 42 from the corner of the rear portion of the nut N.

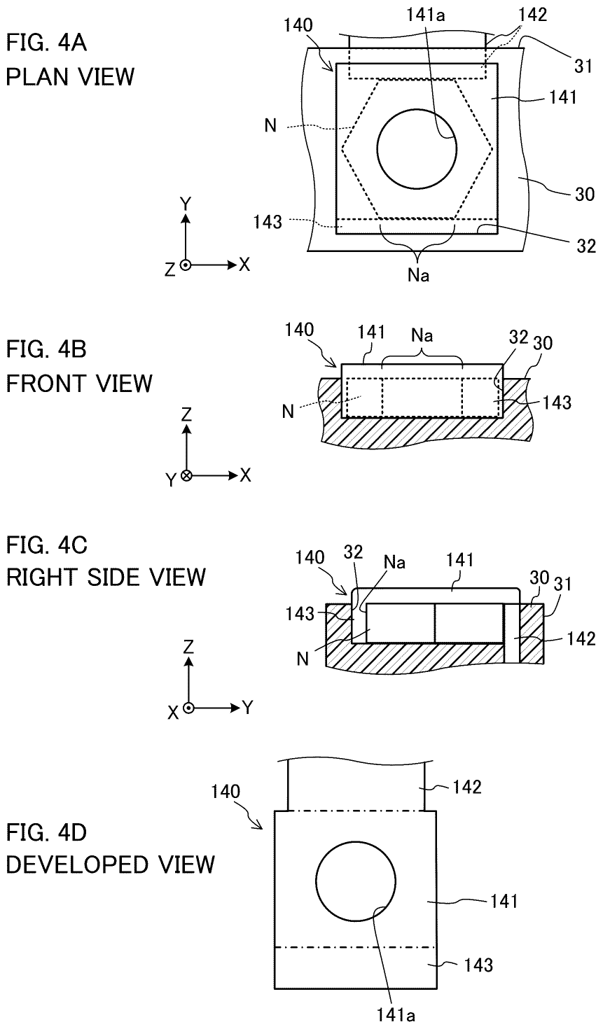

In the bent portions 43 and 43, the position of the lower end is the same as that of one side surface Na (left and right side surfaces) of the abutting nut N. The bent portions 43 and 43 are formed to be greater in width in the Y direction than one side surface Na of the nut N. That is, the bent portions 43 and 43 are formed to be larger than the side surface Na of the nut N. The bent portions 43 and 43 preferably abut on the entire side surface Na of the nut N and spread in at least one of the width direction (Y direction) and the height direction (Z direction) from the contact portion. Although one of the pair of left and right bent portions 43 and 43 may be omitted, the single bent portion 43 is preferably a single bent portion 143 that faces the extending portion 142 to sandwich the nut N as illustrated in FIGS. 4A to 4D to be described later, and a plurality of bent portions 43 not facing the extending portion 42 is desirably provided so as to face each other to sandwich the nut N.

Hereinafter, first to fifth modifications of the present embodiment will be described with reference to FIGS. 4A to 8. Since the portions to be fastened 141, 241, 341, 441 and 541 and the extending portions 142, 242, 342, 442 and 542 of respective modifications can be similar to the portion to be fastened 41 and the extending portion 42 described above, the description thereof will be omitted. In addition, since the N terminal and the M terminal can also be configured similarly to the P terminals 140, 240, 340, 440 and 540, the description thereof is omitted.

FIG. 4A is a plan view, FIG. 4B is a front view, FIG. 4C is a right side view, and FIG. 4D is a developed view of the P terminal 140 according to the first modification.

As illustrated in FIGS. 4A to 4D, the P terminal 140 includes the portion to be fastened 141 including the fastening hole 141a, the extending portion 142 extending from the portion to be fastened 141, and the bent portion 143 bent from the portion to be fastened 141. The bent portion 143 is bent downward from a peripheral edge of an end of the portion to be fastened 141 on a side opposite to the extending portion 142 (negative side in the Y direction), as an example of a peripheral edge of the portion to be fastened 141 different from the extending portion 142 side (positive side in the Y direction). As illustrated in FIGS. 4A and 4C, the bent portion 143 enters between the wall surface (front surface) of the recess 32 of the case 30 and the side surface Na (front surface) of the nut N. The bent portion 143 has a shape that faces the extending portion 142 to sandwich the nut N.

As shown in FIGS. 4A to 4C, it is desirable that the portion to be fastened 141 and the bent portion 143 be formed in a size that fits in the recess 32 of the case 30 in plan view, and the bent portion 143 abuts on both the wall surface (front surface) of the recess 32 and the side surface Na (front surface) of the nut N. The rear surface of the nut N preferably abuts on the extending portion 142.

Six outer peripheral surfaces of the nut N are different in orientation from those of the example illustrated in FIGS. 3A to 3D, and the front surface extending in the XZ plane constitutes one of the side surfaces Na. The left and right corners of the nut N and the left and right side surfaces of the recess 32 are preferably spaced apart from each other so that the torque is not directly applied from the nut N to the wall surface of the recess 32 without passing through the bent portion 143. In the bent portion 143, the position of the lower end is the same as that of the side surface Na (front surface) of the abutting nut N. The bent portions 143 is formed to be greater in width in the X direction than one side surface Na of the nut N. That is, the bent portion 143 is formed to be larger than the side surface Na (front surface) of the nut N. The bent portion 143 preferably abuts on the entire side surface Na (front surface) of the nut N and spreads in at least one of the width direction (X direction) and the height direction (Z direction) from the contact portion.

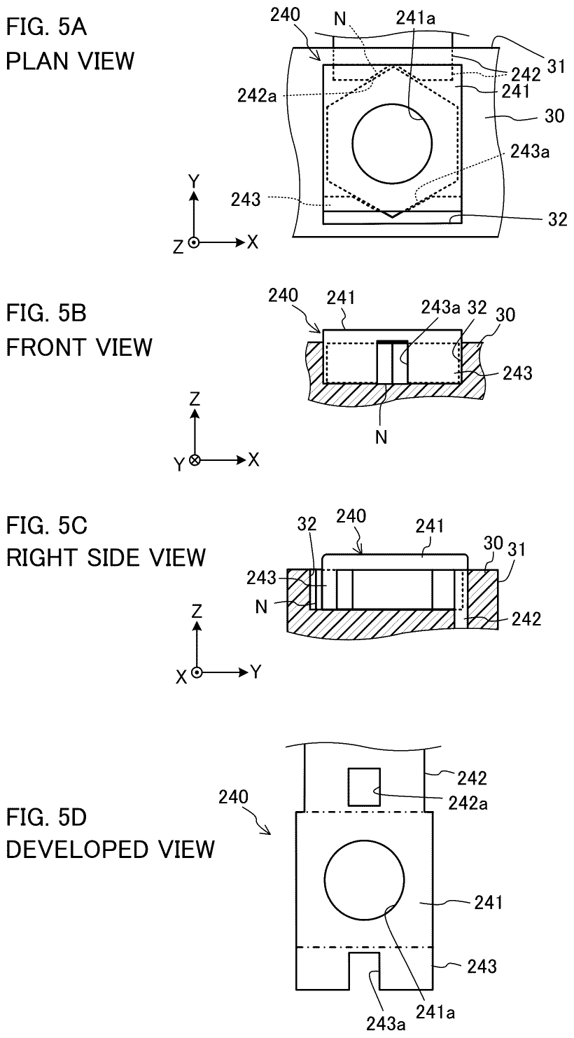

FIG. 5A is a plan view, FIG. 5B is a front view, FIG. 5C is a right side view, and FIG. 5D is a developed view of the P terminal 240 according to the second modification.

As illustrated in FIGS. 5A to 5D, the P terminal 240 includes the portion to be fastened 241 including the fastening hole 241a, the extending portion 242 extending from the portion to be fastened 241, and the bent portion 243 bent from the portion to be fastened 241. The bent portion 243 is bent downward from a peripheral edge of an end of the portion to be fastened 241 on a side opposite to the extending portion 242 (negative side in the Y direction), as an example of a peripheral edge of the portion to be fastened 241 different from the extending portion 242 side (positive side in the Y direction) as in the first modification illustrated in FIGS. 4A to 4D. As illustrated in FIGS. 5A and 5C, the bent portion 243 enters between the wall surface (front surface) of the recess 32 of the case 30 and the nut N. The bent portion 243 has a shape that faces the extending portion 242 to sandwich the nut N.

As shown in FIGS. 5A to 5C, it is desirable that the portion to be fastened 241 and the bent portion 243 be formed in a size that fits in the recess 32 of the case 30 in plan view, and the bent portion 243 abuts on the nut N. In the second modification, there is a gap in the Y direction between the bent portion 243 (and the corner on the front side of the nut N) and the front surface of the recess 32. The bent portion 243 abuts on the wall surface of the recess 32 at the ends on both the left and right sides.

As in the example illustrated in FIGS. 3A to 3D, the six outer peripheral surfaces of the nut N have corners positioned on the front and rear sides, and left and right side surfaces facing the left and right side surfaces of the recess 32. The left and right side surfaces of the nut N and the left and right side surfaces of the recess 32 are preferably spaced apart from each other so that the torque is not directly applied from the nut N to the wall surface of the recess 32 without passing through the bent portions 243, 243. The bent portion 243 has an opening 243a through which a corner (front side) of the nut N is exposed. The extending portion 242 has an opening 242a through which a corner (rear side) of the nut N is exposed. The corner on the front side of the nut N penetrates the bent portion 243 (the opening 243a which is a through hole). The corner on the rear side of the nut N is located in the opening 242a of the extending portion 242. The opening 243a may be a through hole or a recess recessed toward the nut N. In the opening 243a of the bent portion 243 and the opening 242a of the extending portion 242, in plan view, the width in the X direction decreases with increasing distance from the center of the nut N, as the width in the X direction of the front and rear corners of the nut N decreases in a tapered shape toward the apex of the front and rear corners of the nut N. As a result, the bent portion 243 and the extending portion 242 abut on the side surface of the nut N in the openings 243a and 242a to hold the nut N. However, the widths of the openings 242a and 243a in the X direction may be constant. The bent portion 243 has the same lower end position as that of the nut N. Note that the extending portion 242 may not be provided with the opening 242a similarly to the extending portion 42 in FIGS. 3A to 3D, and in this case, the corner of the rear portion of the nut N and the extending portion 242 is preferably spaced apart from each other so that a torque is not applied to the extending portion 242 from the corner of the rear portion of the nut N. The bent portion 243 may be formed along the side surface of the nut N.

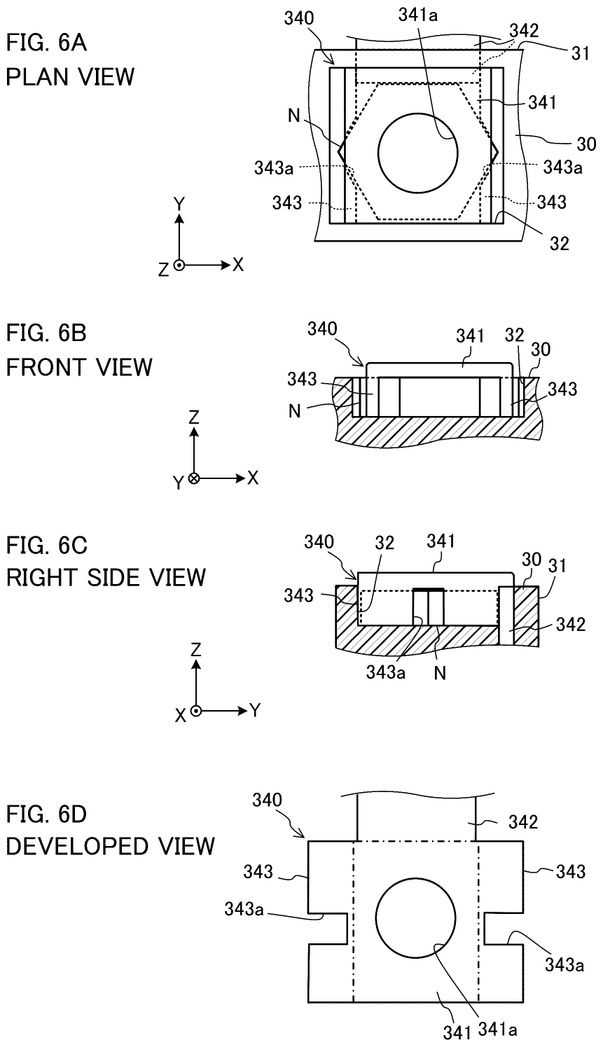

FIG. 6A is a plan view, FIG. 6B is a front view, FIG. 6C is a right side view, and FIG. 6D is a developed view of a P terminal 340 according to a third modification.

As illustrated in FIGS. 6A to 6D, the P terminal 340 includes the portion to be fastened 341 including the fastening hole 341a, the extending portion 342 extending from the portion to be fastened 341, and a pair of bent portions 343, 343 bent from the portion to be fastened 341. The bent portions 343 and 343 are bent downward from both ends of the portion to be fastened 341 in the width direction (X direction) of the P terminal 340 intersecting the extending direction (Y direction) of the extending portion 342, as an example of a peripheral edge of the portion to be fastened 341 different from the extending portion 342 side (positive side in the Y direction), as in the example illustrated in FIGS. 3A to 3D. As illustrated in FIGS. 6A and 6B, the bent portions 343 and 343 enter between the wall surface (left and right side surfaces) of the recess 32 of the case 30 and the nut N.

As shown in FIGS. 6A to 6C, it is desirable that the portion to be fastened 341 and the bent portions 343 and 343 be formed in a size that fits in the recess 32 of the case 30 in plan view, and the bent portions 343 and 343 abuts on the nut N. In the third modification, there is a gap in the X direction between the bent portion 343 (and the left and right corners of the nut N) and the left and right side surfaces of the recess 32. The bent portion 343 abuts on the wall surface of the recess 32 at the ends on the front side.

The six outer peripheral surfaces of the nut N are different in orientation from those of the example illustrated in FIGS. 3A to 3D, and the front surface extending in the XZ plane faces the front surface of the recess 32. The front surface of the nut N and the front surface of the recess 32 are preferably spaced apart from each other so that the torque is not directly applied from the nut N to the wall surface of the recess 32 without passing through the bent portions 343, 343. Each of the bent portions 343 and 343 has an opening 343a through which corners (left and right) of the nut N are exposed. The left and right corners of the nut N penetrate the bent portions 343 and 343. In the openings 343a and 343a of the bent portions 343 and 343, in plan view, the width in the Y direction decreases with increasing distance from the center of the nut N, as the width in the Y direction of the corners of the nut N decreases in a tapered shape toward the apex of the corners of the nut N. As a result, the bent portions 343 and 343 abut on the side surface of the nut N in the openings 343a and 343a to hold the nut N. However, the widths of the openings 343a and 343a in the Y direction may be constant. The bent portion 343 has the same lower end position as that of the nut N. The bent portion 343 may be formed along the side surface of the nut N.

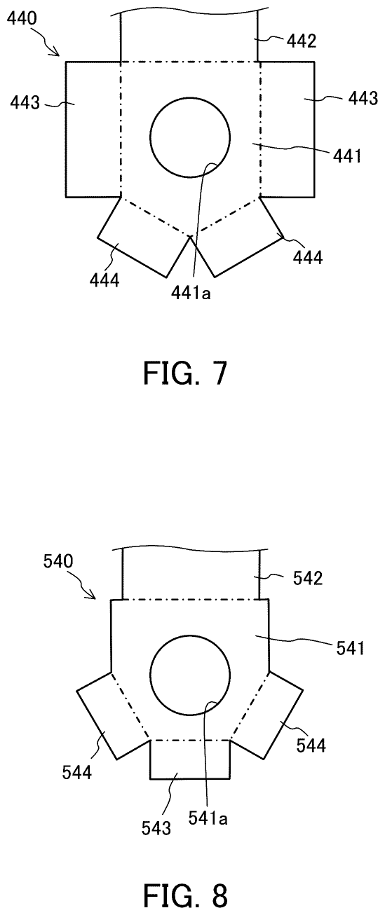

FIG. 7 is a developed view of a P terminal 440 according to a fourth modification.

As illustrated in FIG. 7, the P terminal 440 includes the portion to be fastened 441 including the fastening hole 441a, the extending portion 442 extending from the portion to be fastened 441, and a pair of bent portions 443, 443 and a pair of bent portions 444, 444 bent from the portion to be fastened 441.

The P terminal 40 illustrated in FIGS. 3A to 3D abuts on the left and right side surfaces Na of the nut N only at the bent portions 43 and 43 bent downward from both ends of the portion to be fastened 41 in the width direction (X direction). On the other hand, in the fourth modification, the P terminal 440 includes a pair of bent portions 443, 443 that abuts on the side surface Na of the nut N and the wall surface of the recess 32, and a pair of bent portions 444, 444 that abuts on two front surfaces of the nut N, similarly to the bent portions 43 and 43 of the P terminal 40 illustrated in FIGS. 3A to 3D. In this manner, the P terminal 440 abuts on the four side surfaces of the nut N. The pair of bent portions 444, 444 is formed to have the same size as each of the two front surfaces of the nut N, for example. Note that the pair of bent portions 443, 443 may be omitted, and only at least one bent portion 444 may be provided.

FIG. 8 is a developed view of a P terminal 540 according to a fifth modification.

As illustrated in FIG. 8, the P terminal 540 includes the portion to be fastened 541 including the fastening hole 541a, the extending portion 542 extending from the portion to be fastened 541, and a bent portion 543 and a pair of bent portions 544, 544 bent from the portion to be fastened 541.

The P terminal 140 in the above-described first modification illustrated in FIGS. 4A to 4D abuts on the side surface Na (front surface) of the nut N in the single bent portion 143 bent downward from the peripheral edge of the end of the portion to be fastened 141 on the opposite side (negative side in the Y direction) to the extending portion 142. On the other hand, in the fifth modification, the P terminal 540 includes a bent portion 543 that abuts on the side surface Na (front surface) of the nut N and the wall surface of the recess 32, and a pair of bent portions 544, 544 that abuts on left and right surfaces on the front side of the nut N, similarly to the bent portion 143 of the P terminal 140 illustrated in FIGS. 4A to 4D. In this manner, the P terminal 540 abuts on the three side surfaces of the nut N. The pair of bent portions 544, 544 is formed to have the same size as each of the left and right side surfaces on the front side of the nut N, for example. Note that the bent portions 543 may be omitted, and only at least one bent portion 544 may be provided.

In the present embodiment (and the first to fifth modifications) described above, the semiconductor device 1 includes the semiconductor element 12, the main terminal (for example, the P terminal 40, the N terminal 50, and the M terminal 60), and the case 30. The main terminal includes portions to be fastened 41, 51, and 61 and extending portions 42, 52, and 62 extending from the portions to be fastened 41, 51, and 61 toward the semiconductor element 12 and electrically connected to the semiconductor element 12. The portions to be fastened 41, 51, and 61 include fastening holes 41a, 51a, and 61a, and are fastened to the external conductors C1, C2, and C3 by the screw S and the nut N at the fastening holes 41a, 51a, and 61a. The case 30 accommodates the semiconductor element 12. The case 30 has recesses 32, 33, and 34 for accommodating the nut N. The main terminal further includes the bent portion 43 (63) that is bent from the peripheral edge of the portion to be fastened 41, 51, 61 different from the extending portion 42, 52, 62 side, and enters between a wall surface of the recess 32, 33, 34 in the case 30 and the nut N.

As a result, when the external conductors C1, C2, and C3 are fastened to the main terminal (for example, the P terminal 40, the N terminal 50, and the M terminal 60), the bent portion 43 that enters between the wall surface of the recess 32 and the nut N can receive the torque applied from the nut N. Therefore, according to the present embodiment, it is possible to reduce the torque applied to the case 30 when the external conductors C1, C2, and C3 are fastened to the main terminal. As a result, damage to the case 30 can be suppressed, so that a configuration for ensuring strength of the case 30, such as a configuration in which the case 30 is thick, can be omitted to downsize the semiconductor device 1. Meanwhile, if the attachment between the main terminal and the nut N is loose, the contact resistance between the main terminal and the upper surface of the nut N increases, and the main terminal is more likely to generate heat. In order to suppress this contact resistance, it is conceivable to increase the fastening torque of the screw S. When the fastening torque is increased as described above, the bent portion 43 receives the torque applied from the nut N as in the present embodiment, so that the torque applied to the case 30 can be more effectively reduced.

In the present embodiment and the third and fourth modifications, the P terminals 40, 340, 440, which are an example of the main terminal, has the bent portions 43, 343, 443 bent from the peripheral edges of the portions to be fastened 41, 341, 441 at both ends of the portions to be fastened 41, 341, 441 in the width direction (X direction) of the P terminals 40, 340, 440 intersecting the extending direction (Y direction) of the extending portions 42, 342, 442.

As a result, since the nut N can be sandwiched between the pair of bent portions 43, 343, 443 facing each other, the torque applied to the case 30 can be more reliably reduced.

In the first, second, and fifth modifications of the present embodiment, the extending portions 142, 242, 542 are bent and extend from the portions to be fastened 141, 241, 541 and abut on the nut N. The bent portions 143, 243, 543 are bent from peripheral edges of ends of the portions to be fastened 141, 241, 541 on a side opposite to the extending portions 142, 242, 542.

As a result, since the nut N can be sandwiched between the bent portions 143, 243, 543 and the extending portions 142, 242, 542, the torque applied to the case 30 can be more reliably reduced.

In the present embodiment and the first modification, the bent portions 43,143 abut on the side surface Na of the nut N and are formed to be larger than the side surface Na of the nut N.

As a result, the contact area between the bent portions 43,143 and the wall surface of the recess 32 increases, so that the bent portions 43,143 can distribute the torque applied from the nut N. Therefore, damage to the case 30 can be more reliably suppressed. In addition, since the contact area between the bent portions 43, 143 and the wall surface of the recess 32 is increased, heat dissipation is enhanced.

In the second and third modifications of the present embodiment, the bent portions 243, 343 have openings 243a and 343a through which the corners of the nut N are exposed.

As a result, the material used for the openings 243a and 343a can be reduced, and the bent portions 243, 343 approach the fastening holes 241a and 341a to reduce the portions to be fastened 241, 341, so that the material used for the portions to be fastened 241, 341 can be reduced. Therefore, cost reduction can be achieved. Further, along with downsizing of the portions to be fastened 241, 341, downsizing of the P terminals 240, 340 can be achieved. Furthermore, when the P terminals 240, 340 abut on the nut N in the openings 243a, 343a, the nut N can be more reliably held, and the torque applied to the case 30 can be more reliably reduced.

In the second modification of the present embodiment, the extending portion 242 has an opening 242a through which the corner of the nut N is exposed.

As a result, the material used for the opening 242a can be reduced, and the material used for the portion to be fastened 241 can be reduced by the extending portion 242 approaching the fastening hole 241a to reduce the portion to be fastened 241. Therefore, cost reduction can be achieved. Further, along with downsizing of the portion to be fastened 241, downsizing of the P terminal 240 can be achieved. Furthermore, when the P terminal 240 abuts on the nut N in the opening 242a, the nut N can be more reliably held, and the torque applied to the case 30 can be more reliably reduced.

In the present embodiment (and the first to fifth modifications), the bent portion 43 abuts on the wall surface of the recess 32 of the case 30.

As a result, even if the nut N tries to rotate, the bent portion 43 entering between the wall surface of the recess 32 and the nut N can receive torque from the nut N in a stable state. Therefore, damage to the case 30 can be more reliably suppressed.

Hereinafter, the invention described in the claims of the originally filed application will be additionally described.

### <Supplementary Note 1>

A semiconductor device including:
a semiconductor element;
a main terminal that includes a portion to be fastened including a fastening hole and fastened to an external conductor by a screw and a nut through the fastening hole, and an extending portion extending from the portion to be fastened toward the semiconductor element and electrically connected to the semiconductor element; and
a case that houses the semiconductor element, in which
the case has a recess that accommodates the nut, and
the main terminal further includes a bent portion that is bent from a peripheral edge of the portion to be fastened different from a side of the extending portion, and enters between a wall surface of the recess in the case and the nut.

### <Supplementary Note 2>

The semiconductor device according to Supplementary note 1, in which
the main terminal includes the bent portion bent from the peripheral edge of the portion to be fastened at both ends of the portion to be fastened in a width direction of the main terminal intersecting an extending direction of the extending portion.

### <Supplementary Note 3>

The semiconductor device according to Supplementary note 1, in which
the extending portion is bent and extends from the portion to be fastened and abuts on the nut, and
the bent portion is bent from the peripheral edge of an end of the portion to be fastened opposite to the extending portion.

### <Supplementary Note 4>

The semiconductor device according to any one of Supplementary notes 1 to 3, in which
the bent portion abuts on a side surface of the nut and is formed to be larger than the side surface of the nut.

### <Supplementary Note 5>

The semiconductor device according to any one of Supplementary notes 1 to 3, in which
the bent portion has an opening through which a corner of the nut is exposed.

<Supplementary note 6>

The semiconductor device according to Supplementary note 3, in which
the extending portion has an opening through which a corner of the nut is exposed.

### <Supplementary Note 7>

The semiconductor device according to any one of Supplementary notes 1 to 3, in which
the bent portion abuts on the wall surface of the recess.

As described above, the present invention provides an effect of reducing the torque applied to the case when the external conductor is fastened to the main terminal in the semiconductor device, and thus is valuable to, for example, a power semiconductor device.

What is claimed is:

1. A semiconductor device comprising:
a semiconductor element;
a main terminal that includes:
a fastening portion including a fastening hole, through which the main terminal is fastenable to an external conductor by a screw and a nut, and
an extending portion extending from a first side of the fastening portion toward the semiconductor element, the extending portion being electrically connected to the semiconductor element; and
a case that houses the semiconductor element, wherein
the case has a recess configured to accommodate the nut fastening the main terminal through the fastening hole, and
the main terminal further includes a bent portion that is bent from a peripheral edge of the fastening portion at a second side thereof different from the first side, and that is disposed between a wall surface of the recess in the case and the nut fastening the main terminal through the fastening hole.

2. The semiconductor device according to claim 1, wherein
the bent portion is bent from the peripheral edge of the fastening portion at both the second side and a third side thereof, the second and third sides being opposite to each other in a width direction of the main terminal perpendicular to an extending direction of the extending portion.

3. The semiconductor device according to claim 1, wherein
the extending portion is bent and is configured to abut on the nut fastening the main terminal through the fastening hole, and
the second side is opposite to the first side.

4. The semiconductor device according to claim 1, wherein
the bent portion is configured to abut on a side surface of the nut fastening the main terminal through the fastening hole, and is formed to be larger than the side surface of the nut.

5. The semiconductor device according to claim 1, wherein
the bent portion has an opening through which a corner of the nut fastening the main terminal through the fastening hole is exposed.

6. The semiconductor device according to claim 3, wherein
the extending portion has an opening through which a corner of the nut fastening the main terminal through the fastening hole is exposed.

7. The semiconductor device according to claim 1, wherein
the bent portion abuts on the wall surface of the recess.
